(19) United States
(12) Patent Application Publication
(10) Pub. No.: US 2009/0024887 A1
(43) Pub. Date: Jan. 22, 2009

(54) SEMICONDUCTOR STORAGE DEVICE, DATA WRITE METHOD AND DATA READ METHOD

(75) Inventors: Daijiro Kimbara, Kanagawa (JP); Hiroo Nakano, Kanagawa (JP); Tetsuro Iwamura, Kanagawa (JP); Atsushi Kobayashi, Kanagawa (JP); Masahiko Motoyama, Kanagawa (JP); Hideki Teraoka, Fukuoka (JP); Atsushi Shimbo, Tokyo (JP); Hideo Shimizu, Kanagawa (JP)

Correspondence Address: Gregory Turocy;Amin, Turocy & Calvin, LLP, 24Th Floor, 1900 East 9th Street, Cleveland, OH, 44114, US

(73) Assignee: KABUSHIKI KAISHA TOSHIBA, Tokyo (JP)

(21) Appl. No.: 12/032,877

(22) Filed: Feb. 18, 2008

(30) Foreign Application Priority Data
Feb. 19, 2007 (JP) 2007-038294

(51) Int. Cl. G11C 29/00

(52) U.S. Cl. 714/722

(57) ABSTRACT

A semiconductor storage device includes an arithmetic operation unit configured to perform an arithmetic operation of generating a different error detecting code depending on the information of a memory address, using the data and the information of the memory address in a memory cell into which the data is written, and a storage unit configured to store the data and the error detecting code in the memory cell.

### CROSS-REFERENCE TO RELATED APPLICATION

This application is based upon and claims the benefit of priority from the prior Japanese Patent Application No. 2007-038294 filed on Feb. 19, 2007; the entire contents of which are incorporated herein by this reference.

### BACKGROUND OF THE INVENTION

1. Field of the Invention

The present invention relates to a semiconductor storage device including a memory configured to store data to be protected, a data write method and a data read method.

2. Description of the Related Art

With the proliferation of the Internet, there are increasing transactions over a network from the mobile information terminals including a personal computer, a portable telephone and so on, whereby the secure communication by cryptographic technology is required. Among them, an IC card more difficult to forge and having a higher security than a magnetic card draw attention.

However, for the IC card, various attack methods on encryption have been publicized, and countermeasures against these attack methods are requisite.

One of the attack methods on the IC card is a failure use analysis. This method involves changing a bit pattern of data inside the IC card deliberately by physical means from an outside of the IC card to cause an error in an operation result during the computation of cipher and, analyzing a cryptograph key of secret information.

As an example of attack by the failure use analysis, an attack method against an RSA decoding method using a Chinese remainder theorem (hereinafter referred to as a CRT) is well known, and has been publicized by Boneh and others (e.g., refer to D. Boneh, R. A. DeNillo, and R. J. Lipton, “On the Importance of Checking Computations” Submitted to Eurocrypt” 97).

Among the attack methods against the RSA decoding method using the CRT, a method for falsifying the memory contents is known. A method for detecting the falsification of the memory contents is a measure using an error detecting code (EDC; Error Detecting Code) (e.g., refer to Japanese Patent Application Laid-Open No. 2003-51817).

With this method, an error detecting circuit can detect a falsification in the data portion of memory.

However, when the attacker attacks to try the failure use analysis, it directly falsifies the data portion of memory, but there is another method in which if the attacker attacks on an address decoder, for example, the memory address is changed to access the different memory address from the correct memory address, and read the unexpected illegal data from a memory card IC system.

There is a problem that this attack method for making the attack on the address decoder to read the illegal data, and bring the IC into a failed state can not be detected by the method of Japanese Patent Application Laid-Open No. 2003-51817 as described above.

Accordingly, it is desirable that even when the system reads the unexpected illegal data, an error can be also detected

### SUMMARY OF THE INVENTION

A semiconductor storage device according to one embodiment of the present invention includes a memory configured to store the data and an error detecting code corresponding to the data in a memory cell, an arithmetic operation portion configured to perform an arithmetic operation of generating the different error detecting code depending on a memory address, using the data and the information of the memory address at which the data is written, and a storage portion configured to store the error detecting code in the memory cell.

A data write method according to one embodiment of the invention includes making an arithmetic operation of generating a different error detecting code depending on the information of a memory address, using the data and the information of the memory address in a memory cell into which the data is written, and writing the data and the error detecting code into the memory cell.

A data read method according to one embodiment of the invention includes reading the data and an error detecting code stored in a memory cell from the memory cell designated with a memory address, and making an arithmetic operation of generating an address error detecting code corresponding to the memory address from the memory address, and generating a data error detecting code corresponding to the data from the error detecting code and the address error detecting code.

### BRIEF DESCRIPTION OF THE DRAWINGS

FIG. 1 is a schematic diagram showing the configuration of an IC card chip incorporating a semiconductor storage device according to one embodiment of the present invention;

FIG. 2 is a diagram showing the external appearance of an IC card main body on which the IC card chip shown in FIG. 1 is mounted;

FIG. 3 is a diagram showing the schematic configuration of the semiconductor storage device according to one embodiment of the present invention in an explanatory operation state at the time of writing the data;

FIG. 4 is a flowchart showing the operation contents at the time of writing the data shown in FIG. 3;

FIG. 5 is a diagram showing the schematic configuration of the semiconductor storage device according to one embodiment of the present invention in an explanatory operation state at the time of reading the data;

FIG. 6 is a flowchart showing the operation contents of the data read and verification shown in FIG. 5;

FIG. 7 is an explanatory operation diagram of the data read and verification when the attacker attacks on an address decoder;

FIG. 8 is a diagram showing the configuration in which the data and an error detecting code are stored at the same memory address in a comparative example;

FIG. 9 is an explanatory operation diagram in the case of making an attack of falsifying a bit pattern of data in the configuration shown in FIG. 8; and

FIG. 10 is an explanatory operation diagram in the case of making an attack of falsifying the memory address in the configuration shown in FIG. 8.

### DETAILED DESCRIPTION OF THE PREFERRED EMBODIMENTS

The preferred embodiments of the present invention will be described below with reference to the drawings.

### Embodiment 1

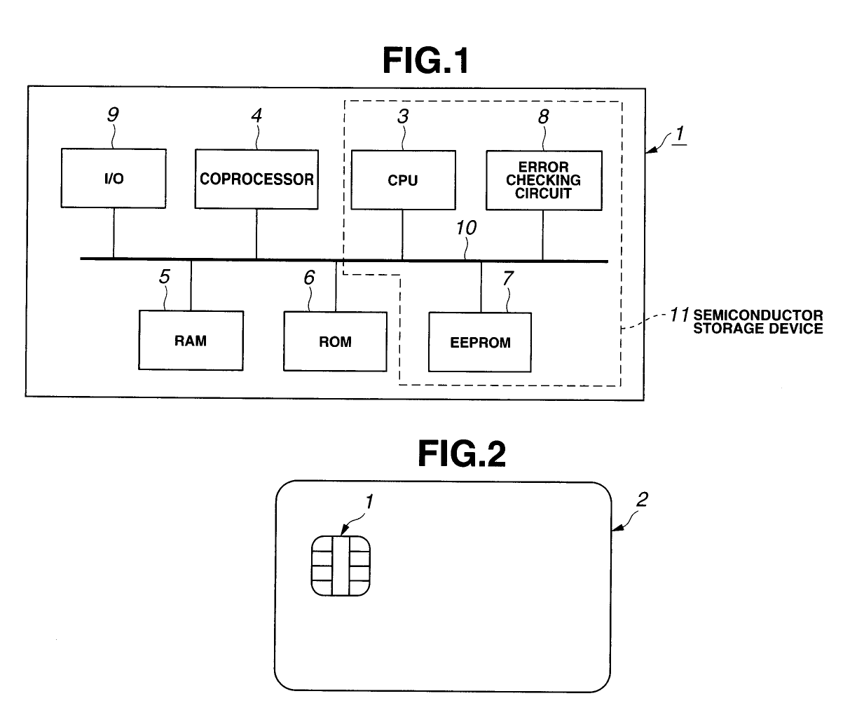

FIG. 1 shows the configuration of an IC card chip 1 including a semiconductor storage device according to an embodiment 1 of the present invention. This IC card chip 1 is mounted on an IC card main body 2 in a business card size, for example, as shown in FIG. 2.

The IC card chip 1 as shown in FIG. 1 has a CPU 3 for controlling the overall operation of the IC card chip 1, a coprocessor 4, a RAM 5, a ROM 6, an EEPROM 7, an error checking circuit 8, an input/output portion (I/O) 9, which are interconnected via a bus 10.

The coprocessor 4 has an auxiliary function of the CPU 3, and performs an arithmetic operation with large computation amounts such as power, remainder and division for an RSA. The RAM 5 is used as a work area with which the CPU 3 performs the read or write operation, or to hold the intermediate result during an encryption process. The ROM 6 is a memory that can be read from the CPU 3, and stores an operation control program for the CPU 3 such as an encryption processing program.

The EEPROM 7 is a non-volatile, electrically rewritable memory that can be read from or written to the CPU 3. In this EEPROM 7, the data to ensure secrecy such as a secret key for use in making the encryption process is stored at a different address from an error detecting code of the data.

The error checking circuit 8 is the circuit configured to check the presence or absence of an error in the data read from the memory such as the EEPROM 7. And the data and the error detecting code read from the memory are firstly taken into this error checking circuit 8, in which the data is verified (checked) by an error detecting method corresponding to the error detecting code. As a result of verification, if there is no error, the data is sent to the CPU 3 or the coprocessor 4 via the bus 10.

On the other hand, as a result of verification, if there is an error, an error detecting signal is outputted. And the CPU 3 is inhibited to perform an encryption process or decoding process, thereby protecting the data or ensuring the data security.

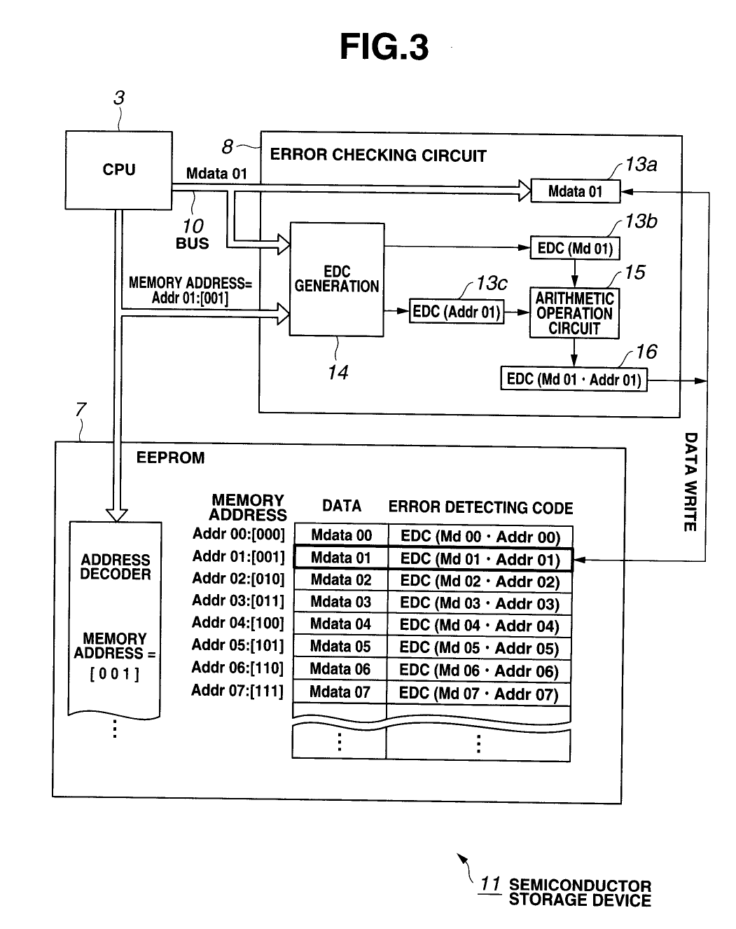

FIG. 3 shows the schematic configuration of the semiconductor storage device 11 according to the present embodiment of the invention in an operation state at the time of writing the data (the data at the time of writing the data has the meaning including the data and the error detecting code corresponding to the data).

In FIG. 3, the semiconductor storage device 11 includes the CPU 3, the EEPROM 7 as the memory and the error checking circuit 8. It may include the coprocessor 4, with the CPU 3.

This error checking circuit 8 internally includes arithmetic operation section configured to perform an arithmetic operation of generating a different error detecting code at least depending on the memory address, using a memory address of a memory cell in which the error detecting code is stored with the data in the memory, and inverse operation section configured to perform an inverse operation that is decoding if the arithmetic operation is encoding, as will be described later (a common arithmetic operation circuit 15 configured to perform the arithmetic operation and inverse operation is provided in a specific configuration example).

The EEPROM 7 is used as the memory in the following explanation, the ROM 6 or RAM 5 may be also applied.

The EEPROM 7 stores the data to be protected and the error detecting code of the data, as shown in FIG. 3. The CPU 3 writes to or reads from the data and the error detecting code corresponding to the data in the EEPROM 7 via an address decoder 12 therein.

In the present embodiment, when the data and the error detecting code corresponding to the data are written into the EEPROM 7, the data is directly written (stored), as shown in FIG. 3. In contrast, the error detecting code corresponding to the data is not directly written, but converted to generate the different error detecting code depending on the value of the memory address by making the arithmetic operation using the information (address data) of the memory address at which the data is written and written into the memory cell at the same memory address as that of the data.

As a specific arithmetic operation example in that case, the exclusive OR operation of the error detecting code corresponding to the data and the address error detecting code as the error detecting code of the memory address in the memory cell into which the data is written is performed from the data.

Also, when the data is read from the EEPROM 7, with the error detecting code corresponding to the data and the memory address, the error detecting code corresponding to the data before the arithmetic operation is generated by performing the inverse operation of the arithmetic operation on the error detecting code, as will be described later.

As the error detecting code written with the data in this manner, the different error detecting code depending on the memory address at which the data is written is generated and written with the data.

Thereby, if the attacker attacks to cause designation of the memory address different from the correct memory address at which each data is written and tries to obtain the data, the generated error detecting code is different from the code corresponding to the correct data, because the memory address is different. Accordingly, the presence of error can be detected by verifying the data with the error detecting code.

The arithmetic operation of generating the different error detecting code depending on the value of the memory address in this manner is performed in the error checking circuit 8 in the present embodiment.

The data (Mdata01 in the specific example of FIG. 3) written into the EEPROM 7 is inputted from the CPU 3 via the bus 10 into the error checking circuit 8, in which the data is stored in a data register 13a, for example, as shown in FIG. 3.

Also, the data is inputted into an error detecting code generation circuit 14 (abbreviated simply as an EDC generator in FIG. 3 and other figures) with the memory address (Addr01:[001] in FIG. 3) at which the data is stored.

This error detecting code generation circuit 14 generates a data error detecting code EDC(Md**) (where ** denotes a value of the memory address) for the data.

The generated data error detecting code EDC(Md**) is stored in a data error detecting code register 13b. Also, the error detecting code generation circuit 14 generates an address error detecting code EDC(Addr**) for the memory address (address data). The generated address error detecting code EDC(Addr**) is stored in an address error detecting code register 13c.

The data stored in the data register 13a is outputted from the error checking circuit 8 to the EEPROM 7, and written into the memory cell at the memory address designated via the address decoder 12 by the CPU 3.

On the other hand, the data error detecting code EDC(Md**) stored in the data error detecting code register 1 3b and the address error detecting code EDC(Addr**) stored in the address error detecting code register 13c are inputted into an arithmetic operation circuit 15 that functions as arithmetic operation means (inverse operation means as will be described later) for the error detecting codes of the data and the memory address.

This arithmetic operation circuit 15 performs a predetermined arithmetic operation on the data error detecting code EDC(Md**) and the address error detecting code EDC(Addr**) to generate an error detecting code EDC(Md**.Addr**) encoded through this arithmetic operation. One example of the arithmetic operations is the exclusive OR operation, for example.

That is, representing the operation code of the exclusive OR as \hat{ }, the arithmetic operation circuit 15 performs the arithmetic operation of [EDC(Md)]\hat{ }[EDC(Addr)] to generate the error detecting code EDC(Md**.Addr**) as the operation result. Accordingly, the error detecting code EDC(Md**.Addr**) becomes the error detecting code (Md**\hat{ }Addr**) in this case.

The error detecting code EDC(Md**.Addr**) generated in this manner is stored in an error detecting code register 16. The error detecting code EDC(Md**.Addr**) stored in the error detecting code register 16 is outputted to the EEPROM 7, like the data, and written into the memory cell at the same memory address at which the data is stored.

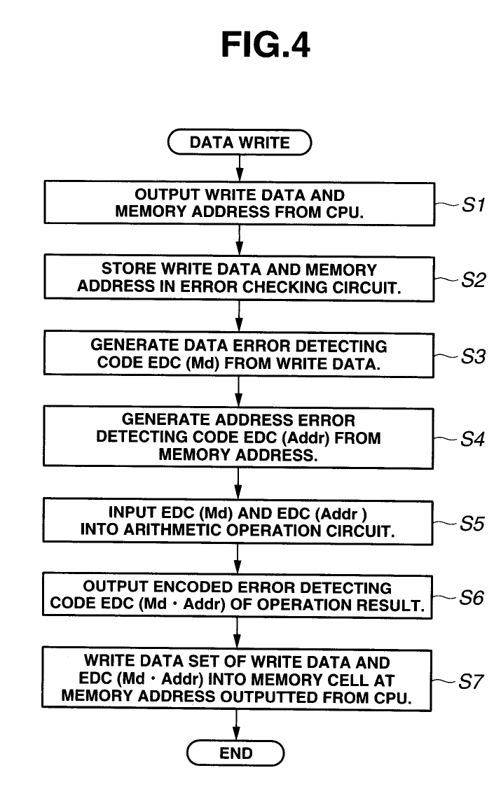

FIG. 4 is a flowchart showing a data write procedure.

If a data write process is started, the write data to be written and the memory address (data) are outputted from the CPU 3 at the first step S1. The write data and the memory address outputted from the CPU 3 are stored in the error checking circuit 8 as indicated at step S2.

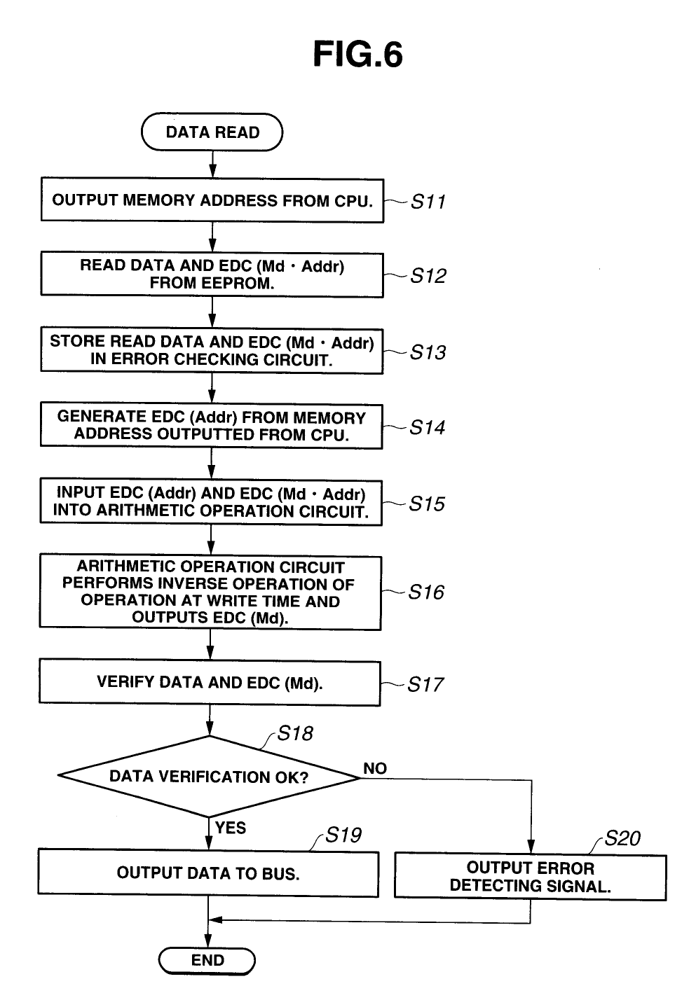

The error detecting code generation circuit 14 within the error checking circuit 8 generates the data error detecting code EDC(Md) from the write data (** is omitted in FIG. 4, and also in FIG. 6) as indicated at step S3. Further, the error detecting code generation circuit 14 generates the address error detecting code EDC(Addr) from the memory address as indicated at step S4.

The data error detecting code EDC(Md) and the address error detecting code EDC(Addr) generated by the error detecting code generation circuit 14 are inputted into the arithmetic operation circuit 15 as indicated at the next step S5. And the arithmetic operation circuit 15 performs a predetermined arithmetic operation to generate the error detecting code EDC(Md-Addr) encoded as the operation result as indicated at step S6.

A data set consisting of the write data at step S1 and the error detecting code EDC(Md-Addr) generated at step S6 is inputted into the EEPROM 7, and written into the memory cell at the memory address outputted from the CPU 3 as indicated at step S7.

Before the data set generated at step S6 is written into the EEPROM 7 at step S7, a process for verifying whether or not there is an error in the operation of the arithmetic operation circuit 15 may be performed. And after verifying that there is no error, the data set may be written at step S7. This verification process may be a data read process as described below.

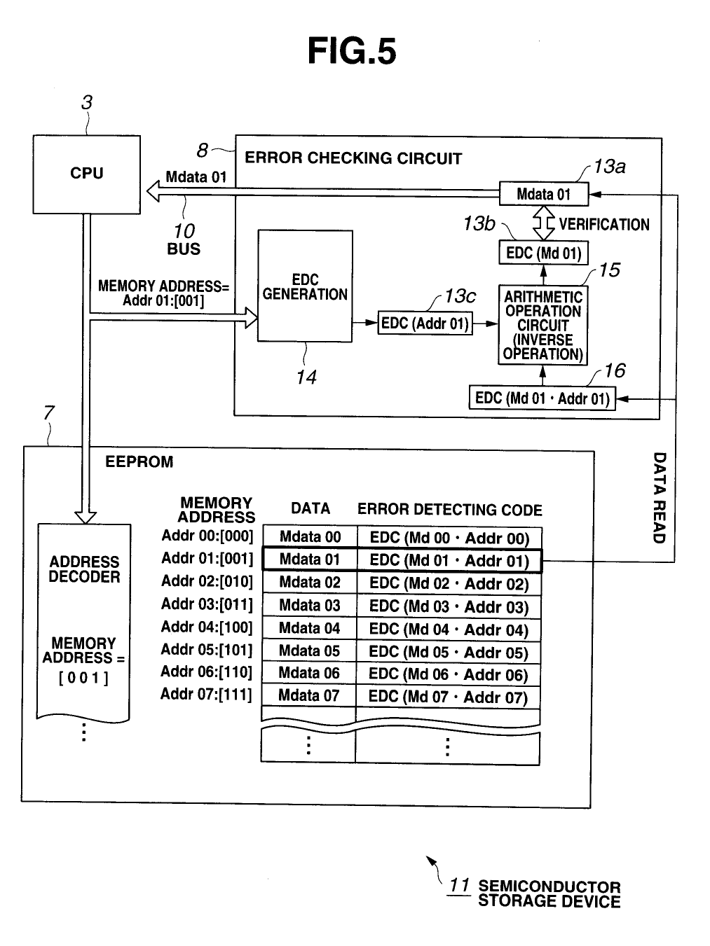

Also, FIG. 5 shows the schematic configuration of the semiconductor storage device 11 in an operation state at the time of reading the data (in this case, the data has the meaning including the data and the error detecting code corresponding to the data).

The CPU 3 outputs the memory address Addr** for reading the data to the address decoder 12 of the EEPROM 7 and the error detecting code generation circuit 14 of the error checking circuit 8.

The EEPROM 7 reads the data set (i.e., data Mdata** and the error detecting code EDC(Md**.Addr**) from the memory cell at the memory address Addr** outputted from the CPU 3.

The read data set is stored in the error checking circuit 8. More specifically, the data Mdata** is stored in the data register 13a and the error detecting code EDC(Md**.Addr**) is stored in the error detecting code register 16.

The above error detecting code generation circuit 14 generates the address error detecting code EDC(Addr**) from the memory address Addr** outputted from the CPU 3, and this address error detecting code EDC(Addr**) is stored in the address error detecting code register 13c. This address error detecting code EDC(Addr**) is inputted into the arithmetic operation circuit 15 that functions as decoding means.

Also, the error detecting code EDC(Md**.Addr**) stored in the error detecting code register 16 is also inputted into the arithmetic operation circuit 15. This arithmetic operation circuit 15 performs the arithmetic operation process of decoding that is inverse to the arithmetic operation process of encoding at the time of writing the data, as described above, to generate the data error detecting code EDC(Md**) for the data.

The arithmetic operation circuit 15 also performs the arithmetic operation process of exclusive OR as the inverse operation, when the arithmetic operation of exclusive OR is performed at the time of writing the data, for example. In this case, the arithmetic operation circuit 15 computes the exclusive OR of the read error detecting code [EDC(Md01)]A[EDC(Addr01)] and EDC(Addr01). This result is changed into the following expressions.

$$\begin{matrix}[ EDC ( Md 01 ) ] \hat{} [ EDC ( Addr 01 ) ] \hat{} [ EDC ( Addr 01 ) ] = [ EDC ( Md 01 ) ] \hat{} 0 \\ = EDC ( Md 01 )\end{matrix}$$

The data error detecting code EDC(Md**) generated through the arithmetic operation process by the arithmetic operation circuit 15 is stored in the error detecting code register 13b.

And the error checking circuit 8 verifies the data Mdata** stored in the data register 13a with the data error detecting code EDC(Md**) generated through the arithmetic operation process by the arithmetic operation circuit 15. In FIG. 5, the verification can be performed without errors, in this case, the verified data Mdata** is outputted to the bus 10.

On the other hand, if it is determined that an error is detected by the verification, the error checking circuit 8 outputs an error detecting signal (data Mdata** where it is determined that there an error is detected by in the verification is not outputted).

Therefore, it is possible to prevent erroneous data Mdata** (information other than the data produced through the arithmetic operation under the essentially correct conditions) from being outputted due to an attack by the attacker.

FIG. 6 shows an operation procedure at the time of reading the data.

If the data read is started, the memory address Addr** for data read is outputted from the CPU 3 as indicated at step S11. This memory address Addr** is outputted to the EEPROM 7 and the error detecting code generation circuit 14 of the error checking circuit 8.

And a data set (i.e., data Mdata** and the error detecting code EDC(Md**.Addr*)) is read from the memory cell at the memory address Addr** in the EEPROM 7 as indicated at step S12.

The read data Mdata** and the error detecting code EDC(Md**.Addr**) are stored in the error checking circuit 8 as indicated at the next step S13. In this case, the data Mdata** is stored in the data register 13a and the error detecting code EDC(Md**.Addr**) is stored in the error detecting code register 16.

The memory address Addr** outputted from the CPU 3 (at step S11) is inputted into the error detecting code generation circuit 14 to generate the address error detecting code EDC(Addr**) as indicated at step S14.

This address error detecting code EDC(Addr**) is stored in the address error detecting code register 13c. And this address error detecting code EDC(Addr**) and the error detecting code EDC(Md**.Addr**) are inputted into the arithmetic operation circuit 15 as indicated at step S15.

The arithmetic operation circuit 15 performs the inverse operation of the arithmetic operation at the time of writing the data to generate (output) the data error detecting code EDC(Md**) for the data as indicated at step S16. This data error detecting code EDC(MD**), unlike the error detecting code EDC(MD**.Addr**), does not include the error detecting code at the memory address Addr**.

The data error detecting code EDC(Md**) is (data) verified with the data Mdata** stored in the data register 13a as indicated at the next step S17. And it is determined whether the data verification is OK or not as indicated at step S18.

If the data verification is OK, namely, if there is no error, the data is outputted to the bus 10 as indicated at step S19. On the other hand, if the data verification is not OK, the error checking circuit 8 outputs an error detecting signal as indicated at step S20. In this manner, the process of FIG. 6 is ended.

With such configurations and operations, when the attacker attacks on the semiconductor storage device 11 to falsify the memory address, or garble the data at the memory address, the semiconductor storage device 11 can detect it to protect the data.

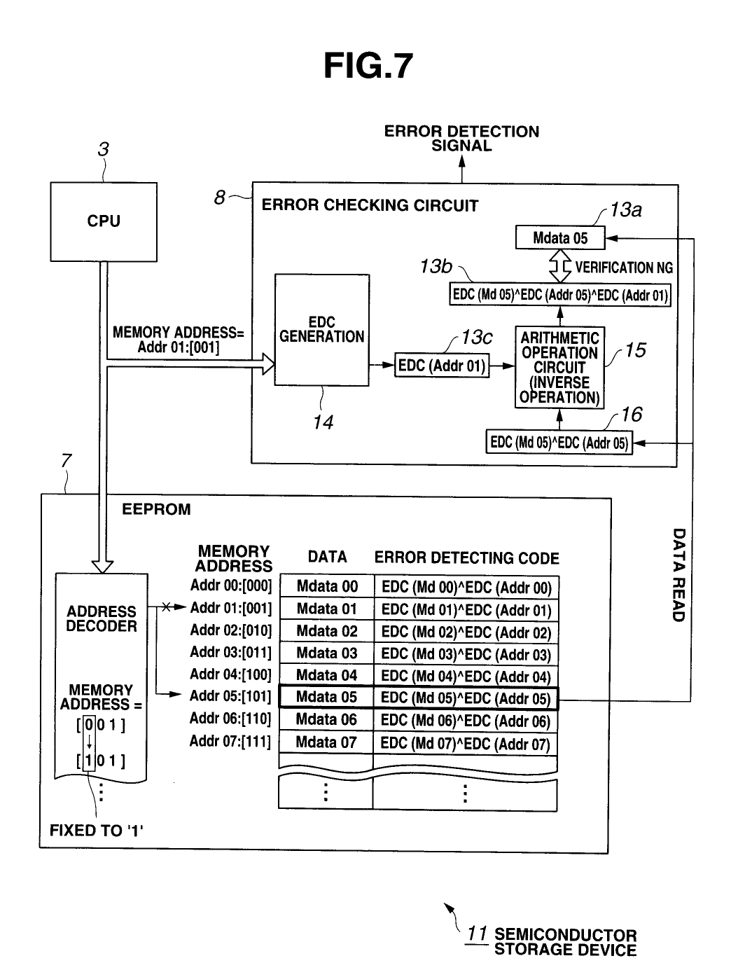

Referring to FIG. 7, the operation will be described below. In a specific explanatory operation example shown in FIG. 7, the encoding of the arithmetic operation circuit 15 is described as the exclusive OR operation.

First of all, in the example of FIG. 7, it is supposed that the most significant bit of the address decoder 12 is fixed to ‘1’ by the attacker. At this time, the CPU 3 gains access to the memory address [001] to read the data ‘Mdata01’, and tries to read the data set [Mdata01, [EDC(Md01)]\hat{ }[EDC(Addr01)].

However, since the most significant bit of the address decoder 12 is fixed to ‘1’, the memory address [101] is actually accessed to read the data set [Mdata05, [EDC(Md05)]\hat{ }[EDC(Addr05)], so that this data set is taken into the error checking circuit 8.

At this time, the error checking circuit 8 performs the following operations (a) to (d), verifies the read data, and performs the process corresponding to the verified result.

(a) For the memory address Addr01:[001] inputted from the CPU 3, the error detecting code generation circuit 14 within the error checking circuit 8 generates the error detecting code EDC(Addr01) at the memory address Addr.

This error detecting code EDC(Addr01) is stored in the address error detecting code register 13c, and used in the following (b).

(b) The arithmetic operation circuit 15 within the error checking circuit 8 performs the exclusive OR operation of the error detecting code [EDC(Md05)]\hat{ }[EDC(Addr05)] read from the EEPROM 7 and the error detecting code EDC(Addr01) generated in (a). This arithmetic operation is the inverse operation of encoding, and corresponds to the operation of decoding. The computation result at this time is expressed by the following expression.

[EDC(Md05)]\hat{ }[EDC(Addr05)]\hat{ }[EDC(Addr01)]

(c) Also, the error checking circuit 8 verifies the data Mdata05 read from the EEPROM 7 and stored in the error checking circuit 8 with [EDC(Md05)]\hat{ }[EDC(Addr05)]\hat{ }[EDC(Addr01)] obtained in the computation of (b), and verifies whether or not there is an error. In this case,

[EDC(Addr05)]\hat{ }[EDC(Addr01)]

Accordingly,

[EDC(Md05)]\hat{ }[EDC(Addr05)]\hat{ }[EDC(Addr01)]≠#EDC(Md05)

The result of verification shows the presence of error.

(d) And the error checking circuit 8 outputs an error detecting signal.

When the erroneous memory address in the memory is directed in this manner, the error checking circuit 8 can detect an error, if the data is read from the EEPROM 7 as the memory.

As a result, the tolerance such as reliability or failure use analysis of the memory, against the attack on the IC card or the like on which the semiconductor storage device 11 is mounted can be improved.

In the present embodiment, when the data is falsified, it is clear that the data is unmatched with the data error detecting code by verification, and the detailed operation explanation is omitted.

Moreover, the error detecting code that can be applied in the present embodiment may be a parity code, a Hamming code or a CRC code, in which the error detecting method is not limited, as far as it can detect the data error.

As one example of the encoding operation and the decoding operation in the arithmetic operation circuit 15, the operation example of exclusive OR has been described above. In this case, there is an advantage that the encoding operation and the decoding operation can be performed by the common exclusive OR operation. Also, it can be implemented through the simple processing.

The operation example of exclusive OR has been described above as one example of the encoding operation and the decoding operation in the arithmetic operation circuit 15, however, the present embodiment is not limited thereto.

When the error detecting code is generated by performing the encoding operation in the arithmetic operation circuit 15, it is possible to employ any arithmetic operation in which the data error detecting code can be generated using the error detecting code and the address error detecting code.

As a simple example, the arithmetic operation circuit 15 may perform the operation of subtracting the error detecting code of the memory address from the data error detecting code at the time of writing the data, generate the different error detecting code depending on the value of the memory address, and perform the inverse operation (of the arithmetic operation) of adding the error detecting code of the memory address to this error detecting code at the time of reading the data. In this case, even if the data is read by falsifying the memory address, an error can be detected because the memory address is different.

In this manner, according to the present embodiment, it is possible to prevent the data Mdata** (information other than the data through the arithmetic operation under the essentially correct conditions) from being outputted (flowed out) due to an attack of the attacker.

In a case where the memory address is artificially changed, such as when the memory address is falsified by the attacker, and in a case where an error simply occurs at the memory address during operation of the IC to change the memory address to read the erroneous data, it is possible to detect the error through the same operation.

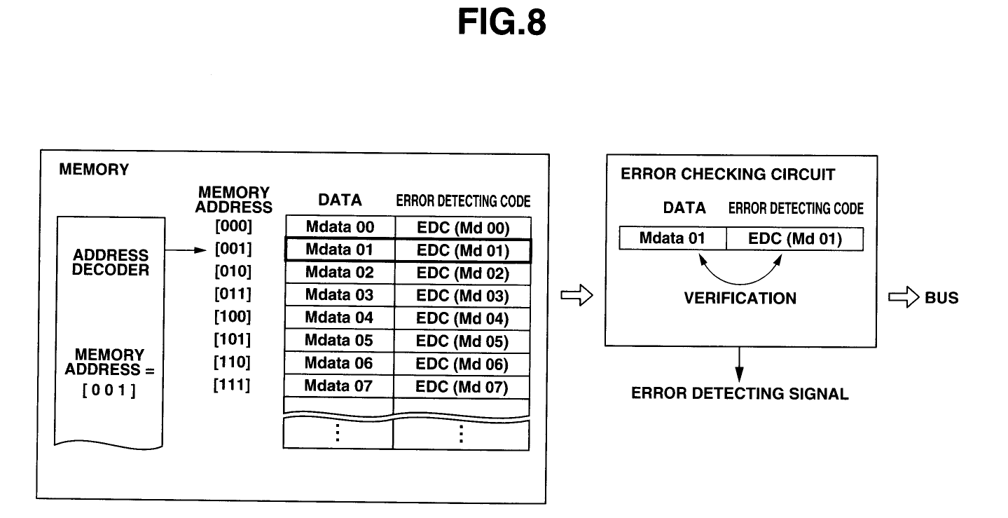

In the above embodiment, a comparative example using the well-known technique will be described below. In the following, the feature of Japanese Patent Application Laid-Open No. 2003-51817 will be described. In this patent application, the memory employs a structure in which the data portion Mdata and the error detecting code EDC(Md) corresponding to this data are stored in the memory cell at the same memory address, as shown in FIG. 8.

A bit width of each memory is the sum of bits for one word of Mdata and a check bit excluding the corresponding Hamming code of Mdata (the bit width required for the check bit is decided by the bit width for one word of Mdata). As one example, when Mdata is 8 bits, the necessary check bit is 4 bits).

With this method, for example, in the case of reading Mdata01 held in the memory address Addr[001] (herein [001] is binary notation), the data set [Mdata01, EDC(Md01)] read from the memory address [001] is taken into the error checking circuit, and it is checked whether or not there is an error in the read data.

At this time, the error checking circuit directly passes the data to the bus, if no error is found by checking the data. However, if an error is found, an error detecting signal is outputted, whereby it is possible to detect the falsification of the memory contents by the attacker.

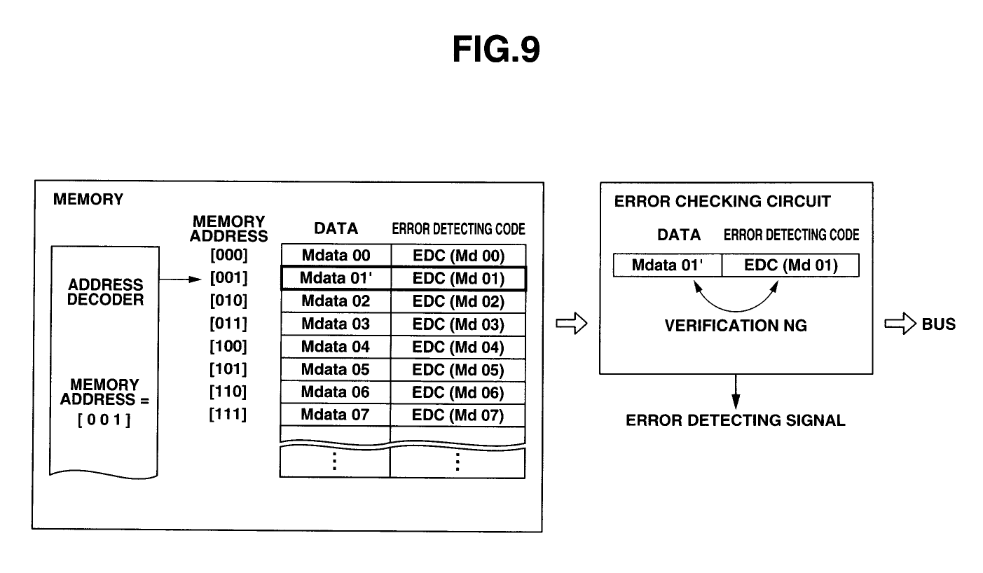

When the attacker actually falsifies the data by changing the bit pattern of the data Mdata01 held at the memory address [001], as shown in FIG. 9, it is supposed that Mdata01 (before falsification) is changed to Mdata01′ (after falsification).

If the data is read from the memory address [001] in this state, the data set [Mdata01, EDC(Md01)] is read and sent to the error checking circuit, and then the data verification is performed. Herein, since EDC(Md01) is the error detecting code corresponding to the data Mdata01 before falsification, the result of verification with the falsified data Mdata01′ is naturally NG (presence of error).

Accordingly, with the method of the above patent, the error detecting circuit can detect the falsification of the data portion in the memory, as shown in FIG. 9.

However, when the attacker attacks to try the failure use analysis, the data in the data portion of the memory is not only directly falsified but also the memory address is changed to access the different memory address from the correct memory address and read wrong data.

There is a problem with an attack method for attacking the address decoder to read illegal data and bring the IC into a failed state, that the method of the above patent application can not detect the error.

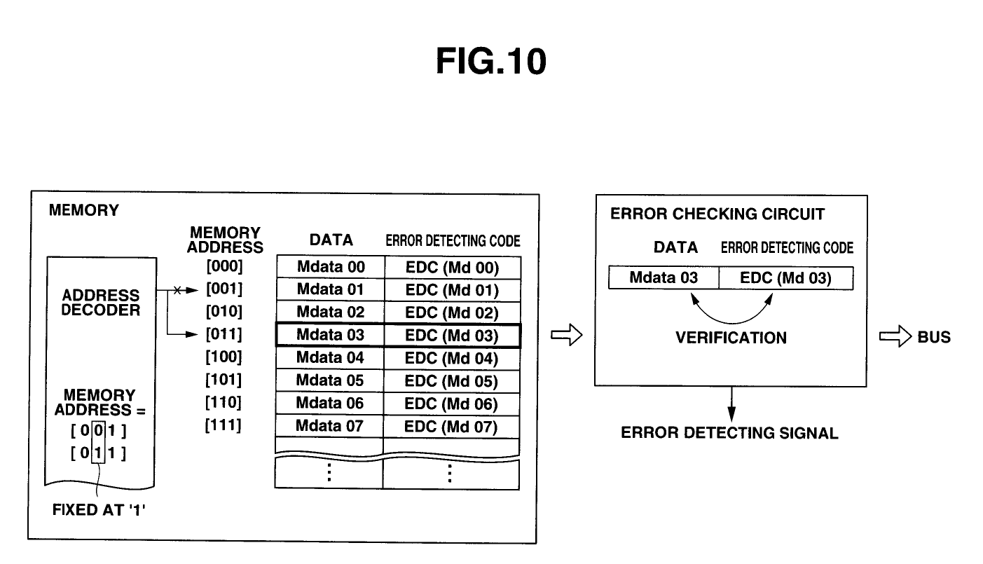

An instance is considered in which in reading Mdata01 held at the memory address [001], the attacker attacks on the address decoder, as shown in FIG. 10.

Though the memory address [001] is specified to read Mdata01, if the most significant bit of the memory address is fixed to ‘1’ by the attacker, the value of the memory address is changed from [001] (before falsification) to [101] (after falsification).

And the data set [Mdata05, EDC(Md05)] at the falsified address [101], but not the data set [Mdata01, EDC(Md01)] at the memory address [001] to be essentially read, is actually read from the memory.

The data set [Mdata05, EDC(Md05)] read at this time is taken into the error checking circuit to check whether or not the data has an error, but the data itself is not falsified, and ‘EDC(Md05)’ is the correct error detecting code corresponding to the read data ‘Mdata05’.

Therefore, the verification result of this data set [Mdata05, EDC(Md05)] in the error checking circuit is “no error”, whereby the error detecting signal is not outputted.

On the contrary, in the above embodiment, when the system reads the unexpected illegal data, the error can be detected.

Having described the embodiments of the invention referring to the accompanying drawings, it should be understood that the present invention is not limited to those precise embodiments and various changes and modifications thereof could be made by one skilled in the art without departing from the spirit or scope of the invention as defined in the appended claims.

What is claimed is:

1. A semiconductor storage device including:
an arithmetic operation portion configured to perform an arithmetic operation of generating a different error detecting code depending on the information of a memory address, using the data and the information of said memory address in a memory cell into which said data is written; and
a storage portion configured to store said data and said error detecting code in said memory cell.

2. The semiconductor storage device according to claim 1, further including an inverse operation portion configured to perform an inverse operation of said arithmetic operation to generate a data error detecting code corresponding to said data.

3. The semiconductor storage device according to claim 2, wherein said arithmetic operation portion also has a function of the inverse operation portion configured to perform said inverse operation simultaneously.

4. The semiconductor storage device according to claim 1, wherein said arithmetic operation portion generates said error detecting code from a data error detecting code corresponding to said data and an address error detecting code corresponding to said memory address of said memory cell in which said data is stored through said arithmetic operation.

5. The semiconductor storage device according to claim 2, wherein said arithmetic operation portion generates said error detecting code from a data error detecting code corresponding to said data and an address error detecting code generated corresponding to said memory address from said memory address of said memory cell in which said data is stored through said arithmetic operation.

6. The semiconductor storage device according to claim 4, wherein said arithmetic operation portion is an exclusive OR operation portion configured to perform an exclusive OR operation of said data error detecting code and said address error detecting code.

7. The semiconductor storage device according to claim 5, wherein said arithmetic operation portion is an exclusive OR operation portion configured to perform an exclusive OR operation of said data error detecting code and said address error detecting code.

8. The semiconductor storage device according to claim 2, further including an error checking portion configured to detect the presence or absence of an error by verifying the operation result generated by the inverse operation of said inverse operation portion with said data.

9. The semiconductor storage device according to claim 1, wherein said semiconductor storage device is mounted in an IC card.

10. A data write method including:
an arithmetic operation of generating a different error detecting code depending on the information of a memory address, using the data and the information of said memory address in a memory cell into which said data is written; and
writing said data and said error detecting code into said memory cell.

11. The data write method according to claim 10, wherein said arithmetic operation includes the arithmetic operation generating a data error detecting code corresponding to said data.

12. The data write method according to claim 10, wherein said arithmetic operation includes the arithmetic operation generating an address error detecting code corresponding to said memory address from said memory address of said memory cell.

13. The data write method according to claim 10, wherein said arithmetic operation is the arithmetic operation generating said error detecting code from an address error detecting code generated corresponding to said memory address from said memory address of said memory cell and an address error detecting code corresponding to said memory address of said memory cell in which said data is stored.

14. The data write method according to claim 10, wherein said arithmetic operation generates said error detecting code through the arithmetic operation including an exclusive OR.

15. The data write method according to claim 13, wherein said arithmetic operation generates said error detecting code from the exclusive OR of said data error detecting code and said address error detecting code.

16. The data write method according to claim 10, further including verifying whether or not said data and the error detecting code generated through said arithmetic operation are the data and the error detecting code in an error free state.

17. A data read method including:
reading the data and an error detecting code stored in a memory cell from said memory cell designated at a memory address; and making an arithmetic operation of generating an address error detecting code corresponding to said memory address from said memory address, and generating a data error detecting code corresponding to said data from said error detecting code and said address error detecting code.

18. The data read method according to claim 17, further verifying whether or not the data error detecting code generated by said arithmetic operation corresponds to said data error detecting code corresponding to said data.

19. The data read method according to claim 17, wherein said arithmetic operation includes the arithmetic operation of the exclusive OR of said error detecting code and said address error detecting code.

20. The data read method according to claim 18, wherein said arithmetic operation includes the arithmetic operation of the exclusive OR of said error detecting code and said address error detecting code.
